(19) United States
(12) Patent Application Publication
(10) Pub. No.: US 2020/0381184 A1
(43) Pub. Date: Dec. 3, 2020

(54) PEROVSKITE SOLAR CELL AND METHOD OF MANUFACTURING THE SAME

(71) Applicant: NATIONAL TAIWAN UNIVERSITY, Taipei City (TW)

(72) Inventors: Wei-Fang SU, Taipei City (TW); Kai-Chi HSIAO, Taipei City (TW)

(21) Appl. No.: 16/659,663

(22) Filed: Oct. 22, 2019

(30) Foreign Application Priority Data
May 30, 2019 (TW) 108118648

(51) Int. Cl. H01G 9/20; H01G 9/00

(52) U.S. Cl. CPC H01G 9/2009; H01G 9/2027; H01L 51/0077; H01G 9/0036; H01G 9/204

(57) ABSTRACT

A perovskite solar cell and a method of manufacturing the same are provided. The perovskite solar cell includes a first electrode, a second electrode, an active layer, a hole transporting layer, electron transporting layer, and a passivation layer. The second electrode is disposed opposite to the first electrode. The active layer is disposed between the first electrode and the second electrode, and the active layer includes a perovskite layer. The hole transporting layer is disposed between the first electrode and the active layer. The electron transporting layer is disposed between the second electrode and the active layer. The passivation layer is disposed between the active layer and the electron transporting layer, and the passivation layer includes a dipolar ion having a heteroaryl group.

### CROSS REFERENCE TO RELATED APPLICATION

This application claims the benefits of the Taiwan Patent Application Serial No. 108118648, filed on May 30, 2019, the subject matter of which is incorporated herein by reference.

### BACKGROUND

### 1. Technical Field

The present disclosure relates to a perovskite solar cell and a method of manufacturing the same, in particular to a perovskite solar cell that mitigates the positive and negative charge defects in the perovskite thin film.

### 2. Description of Related Art

During 2009 to 2014, the power conversion efficiency (PCE) of the perovskite solar cell has been improved from 3.8% up to 19.3%, more than 5 times. The perovskite solar cell is believed to be the solar cell that has a great potential because it has the advantages of low cost and easy manufacture. The perovskite solar cell has been reported to be one of the top 10 breakthroughs in the famous journal, Science, in 2013.

However, in the perovskite thin film of the prior art perovskite solar cell, the uncoordinated lead (Pb²⁺) and halide (X⁻) may induce positive and negative charge defects, resulting in decrease of the carrier transport property and degradation of the perovskite material. This affects both PCE and stability of the perovskite solar cell, and thus limits the development of the perovskite solar cell.

Therefore, ionic defect passivation including positive charge and negative charge is an integral part of the quest for improving the photovoltaic performance of perovskite solar cell.

### SUMMARY

In view of the aforementioned problem, the present disclosure provides a perovskite solar cell and a method of manufacturing the same. The perovskite solar cell includes a passivation layer to mitigate the positive and negative charge defects in the perovskite thin film.

In order to achieve the aforementioned purpose, the present disclosure provides a perovskite solar cell including a first electrode, a second electrode, an active layer, a hole transporting layer, an electron transporting layer, and a passivation layer. The second electrode is disposed opposite to the first electrode. The active layer is disposed between the first electrode and the second electrode, and the active layer includes a perovskite layer. The hole transporting layer is disposed between the first electrode and the active layer. The electron transporting layer is disposed between the second electrode and the active layer. The passivation layer is disposed between the active layer and the electron transporting layer, and the passivation layer includes a dipolar ion having a heteroaryl group.

According to the present disclosure, a passivation layer is introduced into the perovskite solar cell, and the passivation layer can passivate the positive and negative charge defects in the perovskite thin film at the same time, so as to improve the power conversion efficiency (PCE) or stability of the perovskite solar cell.

The present disclosure also provides a method of manufacturing a perovskite solar cell, including: providing a first electrode; forming a hole transporting layer on the first electrode; forming an active layer on the hole transporting layer, the active layer including a perovskite layer; forming a passivation layer on the perovskite layer, the passivation layer including a dipolar ion having a heteroaryl group; forming an electron transporting layer on the passivation layer; and forming a second electrode on the electron transporting layer. The active layer is disposed between the first electrode and the second electrode.

In the present disclosure, the perovskite layer may include perovskite with molecular formula of ABX₃, wherein A may be methylammonium or formamidinium ion, B may be lead, tin, titanium, or tantalum ion, and X may be halogen, but the present disclosure is not limited thereto.

In the present disclosure, the first electrode may be made of indium tin oxide (ITO), fluorine-doped tin oxide (FTO), aluminum zinc oxide (AZO), or zinc indium oxide (IZO), and is not limited to a particular material. Moreover, the second electrode may be made of gold, silver, copper, aluminum, palladium, nickel, or any combination thereof, and is not limited to a particular material.

In the present disclosure, the perovskite solar cell is a perovskite solar cell having a p-i-n structure. The material of the electron transporting layer may include fullerene derivatives, zinc oxide, or titanium oxide, but the present disclosure is not limited thereto. Moreover, the material of the hole transporting layer may include poly(3,4-ethylenedioxythiophene): polystyrene sulfonate (PEDOT: PSS), nickel oxide, molybdenum oxide, 2,2′,7,7′-Tetrakis[N,N-di(4-methoxyphenyl)amino]-9,9′-spirobifluorene (spiro-OMeTAD), N,N′-Bis(3-methylphenyl)-N,N′-bis(phenyl)benzidine (TPD), N,N′-Diphenyl-N,N′-di(p-tolyl)benzidine (PTPD), or poly(3-hexylthiophene-2,5-diyl(P3HT), but the present disclosure is not limited thereto.

In the present disclosure, the passivation layer is disposed directly on a surface of the active layer, so as to directly passivate the positive and negative charge defects in the perovskite layer. The passivation layer includes a dipolar ion having a heteroaryl group. The term “heteroaryl” refers to an aromatic 5-8 membered monocyclic, 8-12 membered bicyclic, or 11-14 membered tricyclic ring system, having one or more heteroatoms (such as O, N, P, or S), for example, thienyl, furyl, pyrazolyl, pyridyl, pyrimidinyl, thiazolyl, benzofuranyl, or benzothiazolyl, but the present disclosure is not limited thereto. Preferably, the dipolar ion a heteroaryl group is a dipolar ion having a thienyl group. The dipolar ion having a thienyl group may include 2-thiophene ethyl ammonium iodide (TEAI), 2-thiophene ethyl ammonium chloride (TEACl), or 2-thiophene ethyl ammonium bromide (TEABr), but the present disclosure is not limited thereto. In one embodiment of the present disclosure, the dipolar ion having a thienyl group is 2-thiophene ethyl ammonium chloride.

In one embodiment of the present disclosure, the perovskite solar cell may further include a work function modified layer disposed between the electron transporting layer and the second electrode. The material of the work function modified layer may include polyethylenimine (PEI), and is not limited to a particular material, but the present disclosure is not limited thereto.

In the present disclosure, forming the first electrode or the second electrode is not limited to a particular method, and it may be formed by chemical vapor deposition (CVD), sputtering, thermal evaporation, Sol-gel process, and so on, but the present disclosure is not limited thereto. In one embodiment of the present disclosure, the first electrode is formed by sputtering. In another embodiment of the present disclosure, the second electrode is formed by thermal evaporation.

In the present disclosure, forming the active layer is not limited to a particular method, and it may be formed by spin coating, blade coating, spraying, roll coating, and so on, but the present disclosure is not limited thereto. In one embodiment of the present disclosure, the active layer is formed by spin coating.

In the present disclosure, forming the passivation layer is not limited to a particular method, and it may be thrilled by spin coating, blade coating, spraying, roll coating, and so on, but the present disclosure is not limited thereto. In one embodiment of the present disclosure, the passivation layer is limited by spin coating.

In the present disclosure, forming the electron transporting layer, the hole transporting layer, or the work function modified layer is not limited to a particular method, and they may be formed by the same method or different methods, such as spin coating, blade coating, spraying, roll coating, and so on, but the present disclosure is not limited thereto.

### BRIEF DESCRIPTION OF THE DRAWINGS

FIG. 1 is the structural diagram of the perovskite solar cell according to one embodiment of the present disclosure;

FIG. 2A shows the photoluminescence (PL) spectra of the perovskite solar cells with and without the passivation layer;

FIG. 2B shows the time-resolved PL spectra (TRPL spectra) of the perovskite solar cell with and without the passivation layer;

FIGS. 3A to 3D show the measurement results of perovskite solar cells with and without TEA halide passivation in the space-charge limited current (SCLC) model;

FIGS. 4A to 4D show the photovoltaic distributions of 24 perovskite solar cells with and without TEACl passivation;

FIG. 4E shows the measurement results of voltage to current density of the perovskite solar cells with and without TEACl passivation;

FIG. 5A shows measurement results of the steady-state photocurrent output PCE measured at the maximum power point; and

FIG. 5B shows the measurement results of the stabilities of the perovskite solar cells stored in a nitrogen filled glove box.

### DETAILED DESCRIPTION OF THE EMBODIMENT

Various embodiments are provided in the following description for the person skilled in this art to clearly understand the advantages and the effects in the present disclosure. Other embodiments may be realized by modifying and varying the details of the disclosed embodiments according to different aspects and applications without departing the spirits of the present disclosure.

Moreover, in the present disclosure and the claims, the ordinal numbers, such as “first”, “second”, and so on, that are presented before the elements, are only used to distinguish the elements having the same name. They do not indicate the arranging orders or the manufacturing orders among the elements. The existence of a greater ordinal number does not necessarily mean the existence of a smaller ordinal number.

Moreover, in the present disclosure and the claims, the terms, such as “on”, “above”, “under”, “below”, and so on, that describe the locations between two elements, may imply direct or indirect contact of the two elements.

The present disclosure provides exemplary embodiments in the following description, but the scope of the present disclosure is not limited thereto. The features of the present disclosure may be combined with other known features to form other embodiments.

### Synthesis of Dipolar Ion

Equimolar hydroiodic acid (Acros, 57% in ethanol), hydrobromic acid (Acros, 33% in acetic acid), and hydrochloric acid (Fisher, 36% in water) are respectively reacted with 2-thiophene ethyl amine (Tokyo Chemical Industry Co., Ltd. 98%), to respectively be synthesized into 2-thiophene ethyl ammonium iodide(TEAI), 2-thiophene ethyl ammonium chloride (TEACl), and 2-thiophene ethyl ammonium bromide (TEABr).

In the example of 2-thiophene ethyl ammonium iodide (TEAI), at first, equimolar hydroiodic acid and 2-thiophene ethyl amine are transferred into a three-necked bottle to form a solution. The solution is vigorously stirred for 2 hours in an ice bath, and then extracted by a rotary evaporator with the solvent removed. Mild yellow powder therefrom is collected and washed by diethyl ether (Fisher, 99%) until its color turns into white, in order to remove the impurities and the residue reactants therein. The powder is recrystallized by anhydrous ethanol (Sigma-Aldrich, 99.5%). Then, white disk-liked precipitates therefrom are collected, and dried in a vacuum oven at 70° C. overnight. Obtained products therefrom are stored in a gloved box filled with nitrogen.

### Manufacture of the Perovskite Solar Cell

A glass substrate coated with fluorine-doped tin oxide (FTO) is provided, and is cleaned in order by deionized water, based solution, methanol, and isopropanol in an ultrasonic bath for 15 minutes. UV-ozone treatment is carried out to clean the FTO substrate again before a hole transporting layer is deposited thereon. The hydrophilic surface of the substrate is helpful to obtain a uniform nickel oxide layer to serve as the hole transporting layer. Methylammonium lead iodide (MAPbI₃) perovskite precursor solution is prepared by dissolving lead iodide (FrontMaterials Co. Ltd.) and methyl ammonium iodide (FrontMaterials Co. Ltd.) into a co-solvent system with dimethyl sulfoxide (Acros, 99.7%): γ-Butyrolactone (Acros, 99⁺%) in 3: 7 v/v. The precursor solution is stirred at 70° C. for 12 hours before being used. For perovskite deposition, the prepared substrate (FTO/NiO) and the precursor solution are preheated on a hot plate respectively at 150° C. and 70° C. for 10 minutes to reach thermal equilibrium. About 50 μL perovskite precursor solution is quickly dropped onto the hot substrate, and then spin coating is performed at 4000 rpm for 15 seconds. The entire process (transferring the substrate from the hot plate to a spin coater, and starting the spin coating) should be finished within 3 seconds to avoid rapid quench of the substrate after it is transferred onto the spin coater. At the beginning of the spin coating, the transparent yellow perovskite precursor turns into a black solid film. The change of the perovskite from the yellow solution to the black solid film indicates that the precursor turns into a crystallized perovskite film. Then, the preheated passivating molecules (1 to 20 mM TEACl, TEABr, and TEAI, in isopropanol and preheated at 70° C. for 10 minutes) are spin coated on the top of the crystallized perovskite film at 3000 rpm for 15 seconds. Before capping an electron transporting layer, which is phenyl-C₆₁-butyric acid methyl ester (PC₆₁BM) in this case, a heat treatment is carried out at 70° C. for 15 minutes to remove the residue solvent, IPA. Then, 20 mg/mL PC₆₁BM (FrontMaterials Co. Ltd. 99%) in chlorobenzene is spin coated on the passivated perovskite film at 1000 rpm for 30 seconds. While, for the device without the passivation layer, PC₆₁BM is directly deposited on the perovskite film with the same conditions. Then, 0.1 wt % work function modifier polyethylenimine (PEI) dispersed in isopropanol is spin coated on the electron transporting layer at 4000 rpm for 30 seconds. A silver electrode with 100 nm thickness and 0.09 cm² active area is thrilled by thermal evaporation. Finally, the (perovskite solar cell) device is completed.

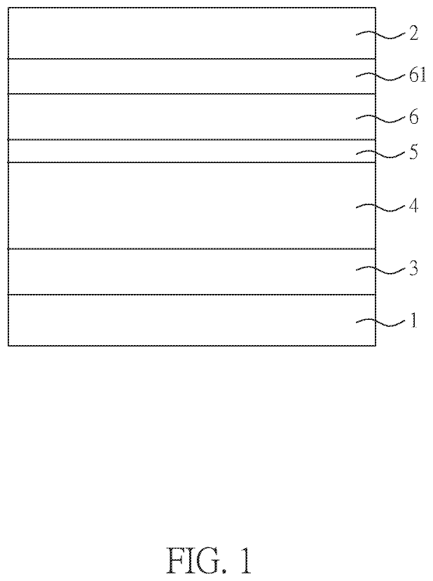

FIG. 1 is the structural diagram of the perovskite solar cell according to one embodiment of the present disclosure. As shown in FIG. 1, the perovskite solar cell manufactured by the aforementioned method includes a first electrode 1, a second electrode 2, a hole transporting layer 3, an active layer 4, a passivation layer 5, an electron transporting layer 6, and a work function modified layer 61. The first electrode 1 is a glass substrate coated with fluorine-doped tin oxide (FTO). The second electrode 2 is a silver electrode, and is disposed opposite to the first electrode 1. The active layer 4 includes a perovskite layer, and is disposed between the first electrode 1 and the second electrode 2. The hole transporting layer 3 is a nickel oxide layer, and is disposed between the first electrode 1 and the active layer 4. The electron transporting layer 6 is PC₆₁BM, and is disposed between the second electrode 2 and the active layer 4. The passivation layer 5 includes a dipolar ion having a heteroaryl group, and is disposed between the active layer 4 and the electron transporting layer 6. The work function modified layer 61 is PEI, and is disposed between the electron transporting layer 6 and the second electrode 2. In other embodiments of the present disclosure, the perovskite solar cell may exclude the work function modified layer 61.

Various types of organo ammonium iodides passivating molecules are used to provide the passivation layers of the perovskite solar cell devices in order to discuss their power conversion efficiencies, and the results are shown in Table 1.

TABLE 1

| | | V_{OC} | J_{SC} | FF | PCE |
|---|---|---|---|---|---|
| | P_{SSV} | (V) | (mA/cm²) | (%) | (%) |
| Ctrl | — | 1.05 ± 0.01 | 19.39 ± 0.048 | 73.26 ± 1.19 | 14.08 ± 0.26 |
| Cmpr 1 | IPA | 0.92 ± 0.03 | 16.4 ± 0.86 | 50.88 ± 4.02 | 7.69 ± 0.41 |
| Cmpr 2 | MAI | 0.94 ± 0.03 | 16.54 ± 0.67 | 56.40 ± 2.70 | 8.76 ± 0.79 |
| Cmpr 3 | PEAI | 1.09 ± 0.00 | 18.08 ± 0.50 | 73.59 ± 1.68 | 14.50 ± 0.31 |
| Embd 1 | TEAI | 1.09 ± 0.01 | 19.20 ± 0.38 | 74.03 ± 1.15 | 15.49 ± 0.38 |

Ctrl: control group;
Cmpr: comparative example;
Embd: embodiment;
P_{SSV}: passivation layer;
IPA: isopropyl alcohol;
MAI: methyl ammonium iodide; and
PEAI: phenyl ethyl aminonium iodide.

It can be observed in the results that, although IPA contains a small amount of active hydrogen (1.67 at. %), when the preheated IPA is dropped onto the perovskite film, the active hydrogen is still reacted with the perovskite and decomposes into volatile methylamine, hydrogen iodide, and lead iodide during a post annealing of the treated film at 70° C. for 15 min. IPA without dipolar ion therefore deteriorates the performance of the device. MAI does not contain unshared electrons that can passivate the cationic defects, and MAI is easily volatile during the post annealing step. That is, the perovskite and MAI that is prepared for passivation are easily decomposed into volatile methylamine, hydrogen iodide, and lead iodide during the post annealing step. After the methylamine and the hydrogen iodide dissipate, the lead iodide reaming on the thin film may disturb the ambipolar properties of the perovskite thin film, and thus decrease the performance of the device. Either PEAI or TEAI can passivate the perovskite thin film, and improve the performance of the device. It is believed that they help the perovskite solar cell devices to enhance PCE because of the containing aromatic groups. The relative large aromatic group of TEAI and PEAI holds advantages in stabilizing cation and being less mobile over the methyl group of MAI does. Thus, they can stay in situ to passivate the defects of perovskite films. Moreover, TEAI exhibits better performance than PEAI does because TEAI contains unshared electrons of thio atoms that can provide better passivating effect. In another aspect, the results may also be explained by pKa, wherein the pKa of MAI=10.64, the pKa of PEAI=9.83, and the pKa of TEAI=9.74. The smaller pKa of TEAI provides more dissociated cations that can further effectively passivate the defects.

The anion (e.g. I⁻) defects and the cation (e.g. Pb⁺) defects in the perovskite are both needed to be passivated, and thus it is equally important to choose the anions and the cations to be the passivating molecules. The passivating effects of different anions are discussed in the following description with fixed cation of TEA, and the results are shown in Table 2.

TABLE 2

| | | V_{OC} | J_{SC} | FF | PCE | Chmp PCE |
|---|---|---|---|---|---|---|
| | P_{SSV} | (V) | (mA/cm²) | (%) | (%) | (%) |
| Ctrl | — | 1.05 ± 0.01 | 19.42 ± 0.56 | 71.70 ± 2.27 | 14.62 ± 0.45 | 15.44 |
| Embd 2 | TEACl | 1.11 ± 0.00 | 20.47 ± 0.67 | 78.30 ± 2.11 | 17.78 ± 0.46 | 18.84 |
| Embd 3 | TEABr | 1.10 ± 0.01 | 19.60 ± 0.78 | 76.46 ± 2.69 | 16.48 ± 0.75 | 17.32 |
| Embd 4 | TEAI | 1.09 ± 0.01 | 19.43 ± 0.77 | 76.86 ± 1.55 | 16.27 ± 0.42 | 17.09 |

Ctrl: control group;
Embd: embodiment;
Pssv: passivation layer; and
Chmp: champion.

Among various types of halide passivating molecules, the device reaches the highest PCE of 18.84% under the best conditions by using TEACl, which has chloride (Cl⁻) anions, because Cl⁻ anion is the smallest anion and exhibits the strongest electron affinity. Moreover, it is reported that Pb—Cl bond shows a stronger bonding than Pb—I bond does. Therefore, compared with other anions, Cl⁻ anions can easily diffuse into the perovskite film, and effectively bond with Pb ion. This implies that the passivating molecules containing Cl⁻ anions can facilitate not only dissociation of the organo ammonium halide, e.g. TEACl, but also its diffusion into the perovskite film to compensate the positively charged anionic defects, e.g. I⁻ vacancies.

It is observed in Table 2 that using TEA halide passivation layer can improve the open circuit voltage V_{OC}, and the improved V_{OC} can enhance the PCE of the perovskite film. In order to evaluate the inherent electronic properties of the perovskite with and without the passivation layer, the energetic disorder of the perovskite film is estimated by Urbach energy with the following Urbach equation:

$$α = {α}_{0} exp ( \frac{E}{{E}_{u}} )$$

wherein α represents the absorption coefficient of perovskite, E represents the photon energy, and Eᵤ represents the Urbach energy. The Eᵤ of the perovskite film without the passivation layer is 24.95 meV, while the Eᵤ of the perovskite films with TEACl, TEABr, and TEAI are 22.65 meV, 23.45 meV, and 22.95 meV, respectively. The results show that the perovskite with TEACl passivation layer has the lowest Eᵤ of 22.65 meV, which means that the least amount of defect states are present in the bandgap.

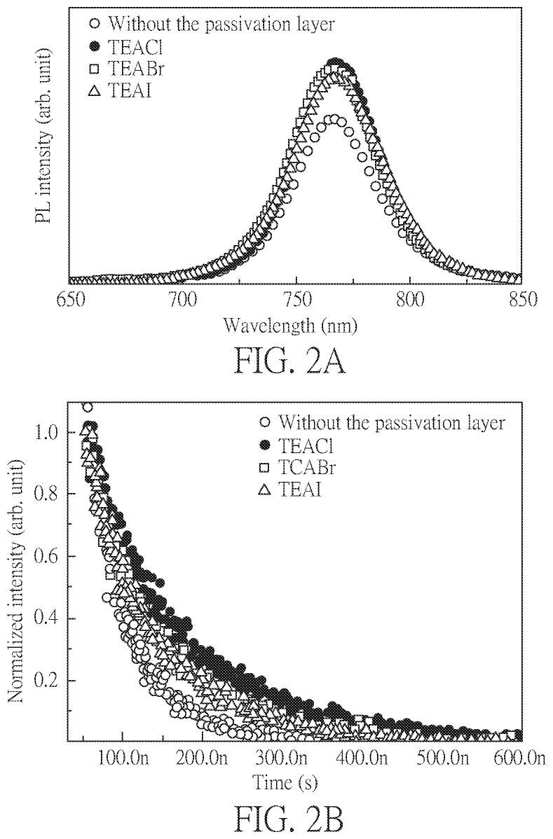

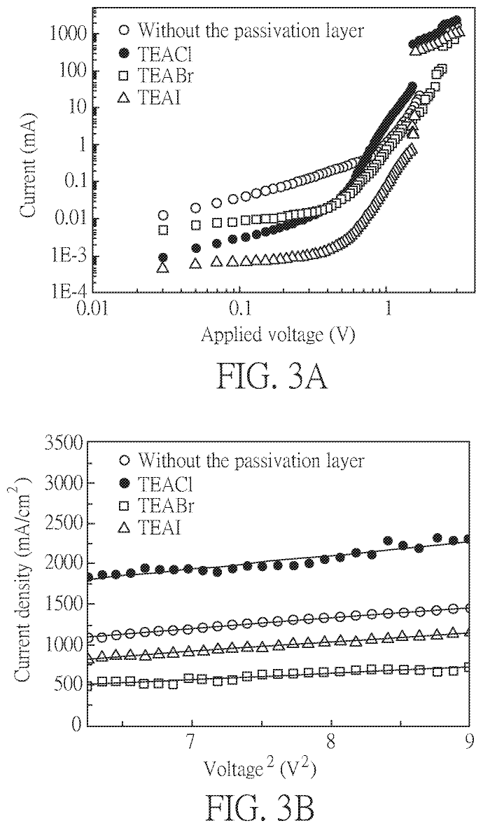

In order to probe the photo-generated carrier dynamics in the perovskite thin films, the photoluminescence (PL) measurements are performed in air at room temperature. Steady-state PL and time-resolved PL (TRPL) are performed by exciting samples by a 440 nm continuous-wave diode laser (DONGWOO, PDLH-440-25). The transient TRPL are continuously recorded by a time correlated single photon counting (TCSPC) spectrometer (WELLS-001 FX, DONGWOO OPTRON) at a frequency of 312.5 MHz in 2 milliseconds (ms). The PL spectra and the TRPL spectra of the perovskite films with and without the passivation layer are respectively shown in FIGS. 2A and 2B. As shown in FIG. 2A, (any of) the perovskite films with the passivation layer exhibits a stronger steady-state PL intensity than the perovskite film without the passivation layer does. Moreover, because of the weak exciton binding energy, the predominant photo-generated carriers in the perovskite are free electrons and holes. The recombination rate of the free carriers can be obtained from TRPL spectra of the perovskite films in FIG. 2B. The average lifetime of charge carriers is calculated by the following equation:

$${τ}_{avg} = \frac{{A}_{1} {τ}_{1} + {A}_{2} {τ}_{2}}{{A}_{1} + {A}_{2}}$$

The results are shown in Table 3.

TABLE 3

| | Average lifetime |
|---|---|
| Passivation layer | (ns) |
| — | 53.46 |
| TEACl | 109.21 |
| TEABr | 76.87 |
| TEAI | 78.19 |

Because (any of) the perovskite film with the passivation layer contains fewer defects and non-radiative recombination, the perovskite film with the passivation layer exhibits a longer average carrier lifetime than the perovskite film without the passivation layer does, which proves that the perovskite film with the passivation layer can inhibit the carrier scavengers caused by the ionic defects. Among the aforementioned passivation molecules, TEACl passivation layer exhibits the best and the longest average carrier lifetime of 109.21 nanoseconds (ns).

It is proved that, when the perovskite solar cell operates in ambient, the ionic defects, particularly the anionic defects, of the perovskite film provide a pathway for oxygen to diffuse fast. In the presence of light, the oxygen molecules occupying the halide vacancies act as electron scavengers. The favorable reaction route allows the electrons generated from the perovskite to directly transfer to the oxygen molecules to form superoxide. The superoxide has a strong oxidation ability that may adversely affect the stability of the perovskite. The perovskite film with TEA halides passivation exhibits a relatively stable PL intensity within 10 minutes continuous measurement, while, the PL intensity of the perovskite film without passivation drops to around 60% of the initial PL intensity. The results show that it is favorable the photo-generated electrons to join the radiative recombination, rather than to transfer to the oxygen to form the superoxide in the passivated films. In this way, the formation of superoxide radicals slows down. Even though it cannot completely avoid the oxygen diffusion into the perovskite, decreasing the ionic defects, particularly the anionic defects, is a key to retard the formation of the superoxide radicals and accordingly enhance the stability of perovskite devices operating in air.

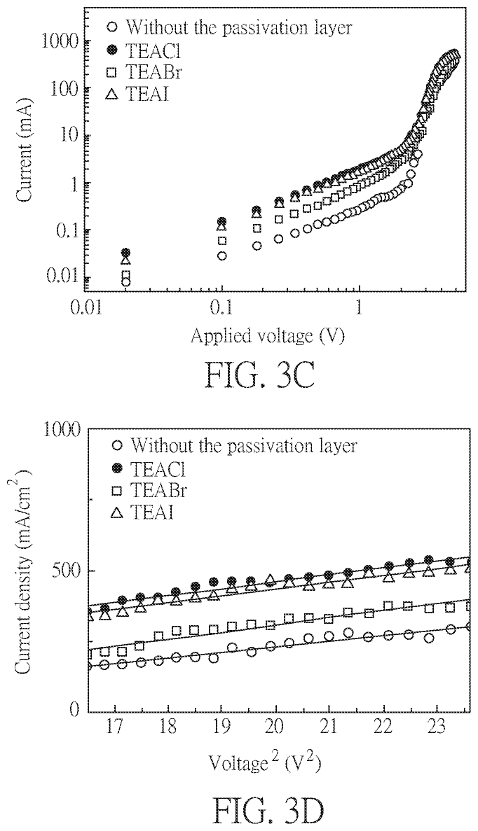

Measurements in space-charge limited current (SCLC) model are performed in order to gain insights into the mobilities and the trapped densities of the perovskite films with and without passivation. FIGS. 3A and 3C respectively show I—V curves of the perovskite films in the devices only with the electron transporting layer and only with the hole transporting layer. The devices only with the electron transporting layer have the following structure: FTO, compacted TiO₂, active layer, PC₆₁BM, PEI, and Au, disposed in order. The devices only with the hole transporting layer have the following structure: FTO, NiO, active layer, and Au, disposed in order. The I—V curves in SCLC model fitting are measured in the dark from 0 to 5 V for the devices only with the electron transporting layer, and from 0 to 8V for the devices only with the hole transporting layer at a scanning rate of 10 ms. The I—V curve may be divided into three regions, an ohmic region (I∝V), a trap-filled limit (TFL) region (I∝Vⁿ, n>2), and a Child's region (I∝V²). The transition point between the ohmic region and the TFL region is called a trap filled limit voltage V_{TFL}, which is derived from the following equation:

$${V}_{TFL} = \frac{e {N}_{t} {d}^{2}}{2 ɛ {ɛ}_{0}}$$

wherein e represents the elementary charge, ε is the dielectric constant of the perovskite, ε₀ is the permittivity of the perovskite, Nₜ is the trap density of the thin film, and d is the thickness of the perovskite film. For the devices only with the electron transporting layer, Nₜ are calculated to be 1.41×10¹⁶, 3.33×10¹⁵, 6.94×10¹⁵, and 5.92×10¹⁵ (carrier numbers/cm³), respectively for the devices having no passivation layer, having TEACl, TEABr, and TEAI passivation. While, for the devices only with the hole transporting layer, Nₜ are calculated to be 3.88×10¹⁶, 1.70×10¹⁶, 2.84×10¹⁶, and 2.85×10¹⁶, respectively for the devices having no passivation layer, and having TEACl, TEABr, and TEAI passivation. This implies that fewer trapped states are presented in the perovskite films with passivation than in the perovskite thin films without passivation for both the devices only with the electron transporting layer or only with the hole transporting layer. The results prove that, the dipolar ion of TEA halides passivation can compensate both types of ionic defects at the same time, and thus decrease the trap density of the perovskite. In the Child's region (applied with high voltage), the carrier mobility (μ) is derived from the following Mott-Gurney Law:

$$J = \frac{9 ɛ {ɛ}_{0} μ {V}^{2}}{8 {d}^{3}}$$

The electron mobility (μₑ) can be derived from FIG. 3B, and the hole mobility (μₕ) can be derived from FIG. 3D. The results are summarized in Table 4, and show that the dipolar ion of TEA halides post treatment enhances the electron mobility and the hole mobility by passivating the ionic defects. In particular, TEACl passivation provides Cl⁻ anions between the perovskite and the electron transporting layer that most significantly enhance the electron mobility, which further facilitates the electron extraction from the perovskite to the electron transporting layer.

TABLE 4

| | Electron mobility | Hole mobility |
|---|---|---|
| Passivation layer | (cm²/V · s) | (cm²/V · s) |
| — | 1.96 | 0.40 |
| TEACl | 4.61 | 1.30 |
| TEABr | 3.44 | 1.12 |
| TEAI | 3.37 | 0.68 |

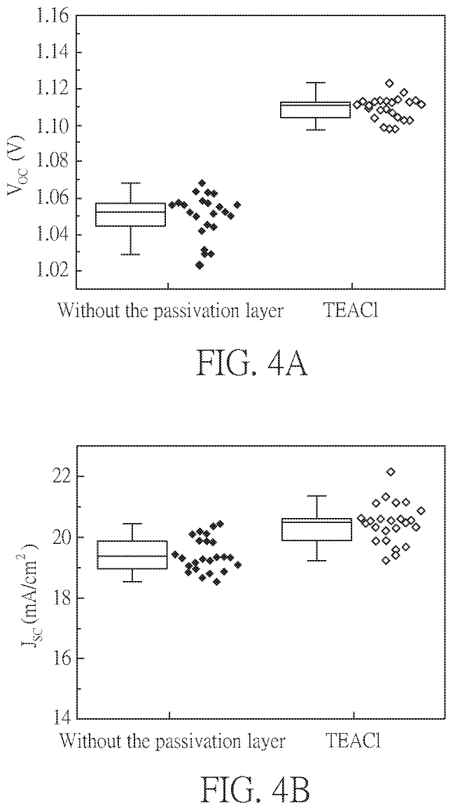

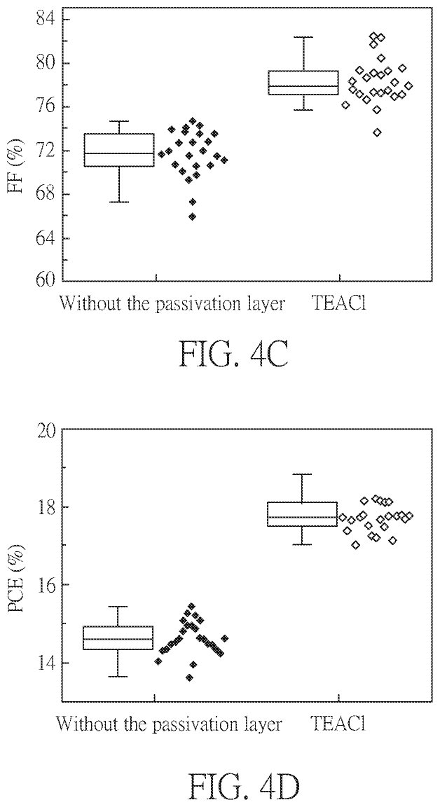

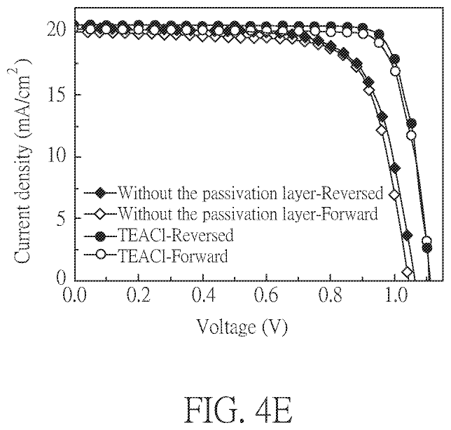

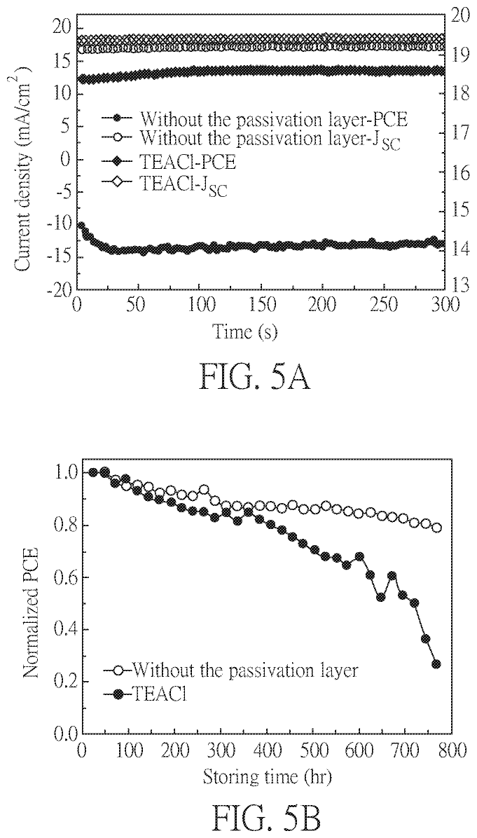

Then, the subsequent tests for reproducibility and stability are performed for TEACl passivation layer, and the results are shown in FIGS. 4A to 5B. FIGS. 4A to 4D show the photovoltaic distributions of 24 perovskite solar cell devices with and without TEACl passivation. The result shows that the TEACl passivated device is a highly reproducible, the average PCE of the perovskite solar cell with TEACl passivation can increase from 14.62% up to 17.78%, and the PCE of the best device is up to 18.84%. The analysis proves that the ionic defects in the perovskite film are successfully passivated, and the passivated perovskite solar cell has increased V_{OC} and PCE.

FIG. 5A shows the measurement results of the steady-state photocurrent output PCE measured at the maximum power point for the perovskite solar cell devices with TEACl passivation and without passivation respectively applied with biases of 0.92 V and 0.84 V. As shown in the 300 second maximum output track, the device with TEACl passivation in the air (with relative humidity of 65% and temperature of 32° C.) exhibits extremely stable output with its PCE drop less than 0.1% when measured after 300 seconds. The PCE still remains over 18.6% when measured after 300 seconds. In contrast, the device without passivation is vulnerable in the air with its PCE drop greater than 8% of the initial PCE. FIG. 5B shows the measurement results of the stabilities of the perovskite solar cells stored in a nitrogen filled glove box. The storing conditions are set to have oxygen smaller than 20.0 ppm and aqueous vapor smaller than 0.10 ppm. It can be obviously observed in the experiment results that for the device with TEACl passivation stored in a nitrogen filled glove box for over 700 hours, its PCE remains over 80% of the initial PCE, while, for the device without passivation, its PCE drops significantly. It thus gives more evidence that suppressing the ionic defects in perovskite film can prevent the device from defect assisted degradation, thereby improving the stability of the device.

The aforementioned embodiments are given only for the purpose of explanation, and are not meant to limit the scope of the present disclosure.

What is claimed is:

1. A perovskite solar cell, comprising:
a first electrode;
a second electrode disposed opposite to the first electrode;
an active layer disposed between the first electrode and the second electrode, and the active layer includes a perovskite layer;
a hole transporting layer, disposed between the first electrode and the active layer;
an electron transporting layer disposed between the second electrode and the active layer; and
a passivation layer disposed between the active layer and the electron transporting layer, and the passivation layer including a dipolar ion having a heteroaryl group.

2. The perovskite solar cell of claim 1, wherein the passivation layer is disposed directly on a surface of the active layer.

3. The perovskite solar cell of claim 1, wherein the perovskite layer includes perovskite with molecular formula of ABX₃, wherein A is Methylammonium or formamidinium, B is lead, tin, titanium, or tantalum ion, and X is halogen.

4. The perovskite solar cell of claim 1, wherein the dipolar ion having a heteroaryl group is a dipolar ion having a thienyl group.

5. The perovskite solar cell of claim 4, wherein the dipolar ion having a thienyl group includes 2-thiophene ethyl ammonium iodide, 2-thiophene ethyl ammonium chloride, or 2-thiophene ethyl ammonium bromide.

6. The perovskite solar cell of claim 1, wherein the first electrode is made of indium tin oxide, fluorine-doped tin oxide, aluminum zinc oxide, or zinc indium oxide.

7. The perovskite solar cell of claim 1, wherein the second electrode is made of gold, silver, copper, aluminum, palladium, nickel, or any combination thereof.

8. The perovskite solar cell of claim 1, wherein the electron transporting layer includes fullerene derivatives, zinc oxide, or titanium oxide.

9. The perovskite solar cell of claim 1, wherein the hole transporting layer includes poly(3,4-ethylenedioxythiophene): polystyrene sulfonate (PEDOT: PSS), nickel oxide, molybdenum oxide, 2,2′,7,7′-Tetrakis[N,N-di(4-methoxyphenyl)amino]-9,9′-spirobifluorene (spiro-OMeTAD), N,N′-Bis(3-methylphenyl)-N,N′-bis(phenyl)benzidine (TPD), N,N′-Diphenyl-N,N′-di(p-tolyl)benzidine (PTPD), or poly(3-hexylthiophene-2,5-diyl (P3HT).

10. A method of manufacturing a perovskite solar cell, comprising:
providing a first electrode;
forming a hole transporting layer on the first electrode;
forming an active layer on the hole transporting layer, the active layer including a perovskite layer;
forming a passivation layer on the perovskite layer, the passivation layer including a dipolar ion having a heteroaryl group;
forming an electron transporting layer on the passivation layer; and
forming a second electrode on the electron transporting layer,
wherein the active layer is disposed between the first electrode and the second electrode.

11. The method of claim 10, wherein the passivation layer is formed directly on a surface of the active layer.

12. The method of claim 10, wherein the active layer is formed on the hole transporting layer.

13. The method of claim 10, wherein the perovskite layer includes perovskite with molecular formula of ABX₃, wherein A is methylammonium or formamidinium ion, B is lead, tin, titanium, or tantalum ion, and X is halogen.

14. The method of claim 10, wherein the dipolar ion having a heteroaryl group is a dipolar ion having a thienyl group.

15. The method of claim 14, wherein the dipolar ion having a thienyl group includes 2-thiophene ethyl ammonium iodide, 2-thiophene ethyl ammonium chloride, or 2-thiophene ethyl ammonium bromide.

16. The method of claim 10, wherein the first electrode is made of indium tin oxide, fluorine-doped tin oxide, aluminum zinc oxide, or zinc indium oxide.

17. The method of claim 10, wherein the second electrode is made of gold, silver, copper, aluminum, palladium, nickel, or any combination thereof.

18. The method of claim 10, wherein the electron transporting layer includes fullerene derivatives, zinc oxide, or titanium oxide.

19. The method of claim 10, wherein the hole transporting layer includes poly(3,4-ethylenedioxythiophene): polystyrene sulfonate (PEDOT: PSS), nickel oxide, molybdenum oxide, 2,2′,7,7′-Tetrakis[N,N-di(4-methoxyphenyl)amino]-9,9′-spirobifluorene (spiro-OMeTAD), N,N′-Bis(3-methylphenyl)-N,N′-bis(phenyl)benzidine (TPD), N,N′-Diphenyl-N,N′-di(p-tolyl)benzidine(PTPD), or poly(3-hexylthiophene-2,5-diyl) (P3HT).
